(19) United States
(12) Patent Application Publication
(10) Pub. No.: US 2018/0260319 A1
(43) Pub. Date: Sep. 13, 2018

(54) WRITING SSD SYSTEM DATA

(71) Applicant: Toshiba Memory Corporation, Tokyo (JP)

(72) Inventors: Leland Thompson, San Jose, CA (US); Chris Delaney, San Jose, CA (US); Gordon Waidhofer, San Jose, CA (US)

(21) Appl. No.: 15/455,570

(22) Filed: Mar. 10, 2017

(51) Int. Cl. G06F 12/02; G11C 16/10; G06F 12/1009

(52) U.S. Cl. CPC G06F 12/0246; G11C 16/10; G06F 2212/7201; G06F 2212/2022; G06F 12/1009

(57) ABSTRACT

A solid state drive (SSD) and a method for writing user data and system data is disclosed. In one embodiment, the SSD includes a memory controller, a host interface communicatively coupled to the memory controller, and one or more NAND flash memory devices communicatively coupled to the memory controller. The memory controller is configured to write both a user data received via the host interface and a system data generated by the memory controller to one or more blocks of the NAND flash memory devices such that the one or more blocks contain both user data and system data. In one embodiment, the memory controller is figured to divide the system data into one or more segments having a uniform size, and append a header to each segment of system data before writing the system data to the one or more blocks of the NAND flash memory devices.

### FIELD OF THE INVENTION

This invention generally relates to data storage techniques for a solid state drive (SSD).

### BACKGROUND OF THE INVENTION

SSDs typically include non-volatile flash-based memory, such as NAND flash memory devices, a volatile memory buffer, such as DRAM and/or SRAM, and a memory controller communicatively coupled to the non-volatile flash-based memory and the volatile memory buffer. The NAND flash memory devices are subdivided into distinct areas for storing user data, which is received from an external host device via a host interface on the SSD, and system data, which is generated internally by the memory controller. User data and system data are stored in different formats, and certain parts of the system data are written less frequently than user data. Therefore user data and system data must be handled differently. Two different algorithms are used by the memory controller to write user data and system data. Processes for data management, including garbage collection, error correction, and wear leveling, are also performed using two different algorithms for user data and system data.

The need for parallel and duplicative algorithms for writing and processing user data and system data presents a number of issues. The use of two different algorithms slows down the SSD development process because each algorithm must be independently developed, debugged, and deployed. The use of two different algorithms also slows the performance of the SSD because the memory controller must differentiate between user data and system data when implementing processes for data management.

There is, therefore, an unmet demand for data storage techniques for SSDs that allow a single algorithm to be used for processing both user and system data.

### BRIEF DESCRIPTION OF THE INVENTION

In one embodiment, an SSD includes a memory controller, one or more NAND flash memory devices communicatively coupled to the memory controller, and a host interface communicatively coupled to the memory controller. In one embodiment, the memory controller is configured to write both a user data received via the host interface and a system data generated by the memory controller to one or more blocks of the NAND flash memory devices such that the one or more blocks contain both user data and system data.

In one embodiment, the memory controller is further configured to divide the system data into one or more segments having a uniform size. The memory controller is further configured to append a header to each segment of system data before writing the system data to the one or more blocks of the NAND flash memory devices. In one embodiment, the header includes at least one of a logical address associated with a segment of user or system data, a time stamp, and a valid bitmap status.

In one embodiment, the NAND flash memory devices are configured to store user data and system data in one or more segments, each segment of user data and each segment of system data having a physical address location on the NAND flash memory devices and a logical address comprising a namespace identifier indicating a namespace and a logical block within the namespace. In one embodiment, the memory controller is further configured to assign a namespace identifier to each segment of system data.

In one embodiment, the system data includes at least one of a bad sector list, a debug log, and firmware. In another embodiment, the system data includes a user logical-to-physical (User L2P) table translating logical addresses of one or more segments of user data to physical address locations. In one embodiment, the User L2P table includes a first map translating the namespace identifier of each of the one or more logical address to a starting segment of user data on the one or more NAND flash memory devices, and a second map translating the logical block of each of the one or more logical address to a segment of user data on the one or more NAND flash memory devices.

In one embodiment, the memory controller is further configured to write a system logical-to-physical (System L2P) table translating logical addresses of one or more segments of system data to one or more physical address locations of the segments of system data on the NAND flash memory devices. In one embodiment, the System L2P table includes a first map translating the namespace identifier of each of the one or more logical addresses to a starting segment of system data on the one or more NAND flash memory devices, and a second map translating the logical block of each of the one or more logical addresses to a segment of system data on the one or more NAND flash memory devices.

In one embodiment, the one or more NAND devices includes a reserved area. In one embodiment, the memory controller is further configured to write the System L2P to the reserved area when the SSD experiences a power loss or other failure event.

In one embodiment, a method of writing user data and system data to one or more NAND flash memory devices communicatively coupled to a memory controller within an SSD includes receiving the user data via a host interface communicatively coupled to the memory controller. The method further includes generating the system data with the memory controller. The method further includes writing both the user data and the system data to one or more blocks of the NAND flash memory devices such that the one or more blocks contain both user data and system data.

In one embodiment, the method further includes dividing the system data into one or more segments having a uniform size. The method further includes appending a header to each segment of system data before writing the system data to the one or more blocks of the NAND flash memory devices. In one embodiment, the header includes at least one of a logical address associated with a segment of user or system data, a timestamp, and a valid bitmap status.

In one embodiment, the method further includes writing the user data and system data in one or more segments, each segment of user data and each segment of system data having a physical address location on the NAND flash memory devices and a logical address comprising a namespace identifier indicating a namespace and a logical block within the namespace. The method further includes assigning a namespace identifier to each segment of system data before writing both the user data and the system data to one or more blocks of the NAND flash memory devices such that the one or more blocks contain both user data and system data.

In one embodiment, the system data includes at least one of a bad sector list, a debug log, and firmware. In another embodiment, the system data includes a User L2P table translating logical addresses of one or more segments of user data to physical address locations. In one embodiment, the User L2P table includes a first map translating the namespace identifier of each of the one or more logical addresses to a starting segment of user data on the one or more NAND flash memory devices, and a second map translating the logical block of each of the one or more logical addresses to a segment of user data on the one or more NAND flash memory devices.

In one embodiment, the method further includes writing to the NAND flash memory devices a System L2P table translating logical addresses of one or more segments of system data to one or more physical address locations of the segments of system data on the NAND flash memory devices. In one embodiment, the System L2P table includes a first map translating the namespace identifier of each of the one or more logical addresses to a starting segment of system data on the one or more NAND flash memory devices, and a second map translating the logical block of each of the one or more logical addresses to a segment of system data on the one or more NAND flash memory devices.

In another embodiment, the method further includes writing the System L2P to a reserved area on the NAND flash memory devices when the SSD experiences a power loss or other failure event.

### BRIEF DESCRIPTION OF THE FIGURES

FIG. 1 is a block diagram of an SSD, according to one embodiment of the invention.

FIG. 2 shows the process of writing a system data to a blended data block of user and system data on a NAND flash memory device, according to one embodiment of the invention.

FIG. 3A shows a segment of user data stored on a NAND flash memory device, according to one embodiment of the invention.

FIG. 3B shows a system data stored on a NAND flash memory device, according to the prior art.

FIG. 3C shows a segment of system data on a NAND flash memory device that has been configured to look like a segment of user data, according to one embodiment of the invention.

FIG. 4 shows a blended data block of user and system data on a NAND flash memory device, according to one embodiment of the invention.

FIG. 5 shows the steps of writing system data to one or more NAND flash memory devices, according to one embodiment of the invention.

FIG. 6 shows the steps of processing a blended data block of user and system data on one or more NAND flash memory devices, according to one embodiment of the invention.

### DETAILED DESCRIPTION OF THE INVENTION

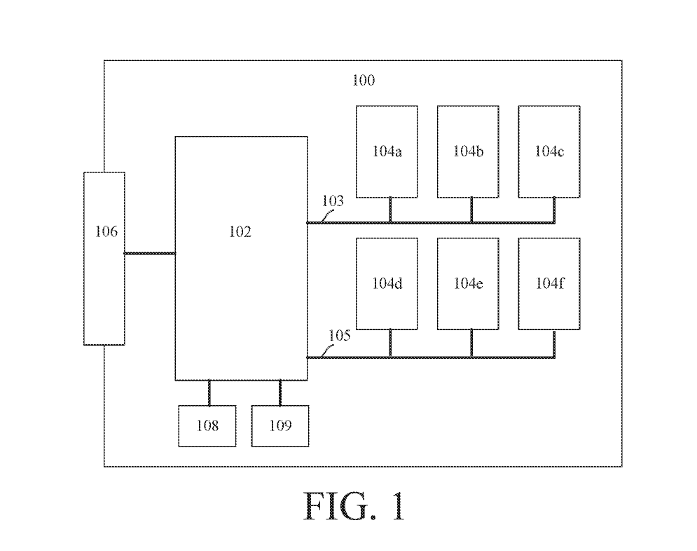

FIG. 1 is a block diagram of an SSD 100, according to one embodiment of the invention. As shown in FIG. 1, the SSD 100 has a host interface 106 that allows the SSD 100 to be connected to a host device (not shown). The host device may be any suitable device, such as a computer or a storage appliance. The host interface 106 may be any suitable interface that facilitates communication between the SSD 100 and the host device, such as a Peripheral Component Interconnect Express™ (PCIe or PCI Express) interface, a Serial ATA™ (SATA) interface, Serial Attached SCSI™ (SAS), etc.

The SSD 100 includes a memory controller 102 in communication with a DRAM 108, an SRAM 109, and an array of NAND flash memory devices 104a-f. The memory controller 102 manages the writing, reading, and erasing of data stored on the NAND flash memory devices 104a-f of the SSD 100, and facilitates communication with the host device over the host interface 106. The memory controller 102 receives user data from a host device via the host interface 106. The memory controller 102 also internally generates system data. In one embodiment, the firmware of the memory controller 102 implements various data management processes on the data stored on the NAND flash memory devices 104a-f, including garbage collection, error correction, and wear leveling. The memory controller 102 may use DRAM 108 and SRAM 109 as buffers for storing data, for performing error correction parity encoding, and the like.

The NAND flash memory devices 104a-f are arranged in two channels 103 and 105 in communication with the memory controller 102. While six NAND flash memory devices 104a-f are shown in the SSD 100 in FIG. 1, the specific number of NAND flash memory devices and channels are not limited, and may be one or more NAND flash memory devices arranged in one or more channels within the scope of the present invention. The number of NAND flash memory devices and channels of such devices in communication with the memory controller 102 within the SSD 100 will depend on the configuration of the SSD 100, including the overall amount of user data storage specified, the storage density and type of NAND flash memory used, and so forth. In one embodiment, the NAND flash memory devices 104a-f are MLC NAND media devices, or TLC NAND media devices, or QLC NAND media devices, or a combination thereof.

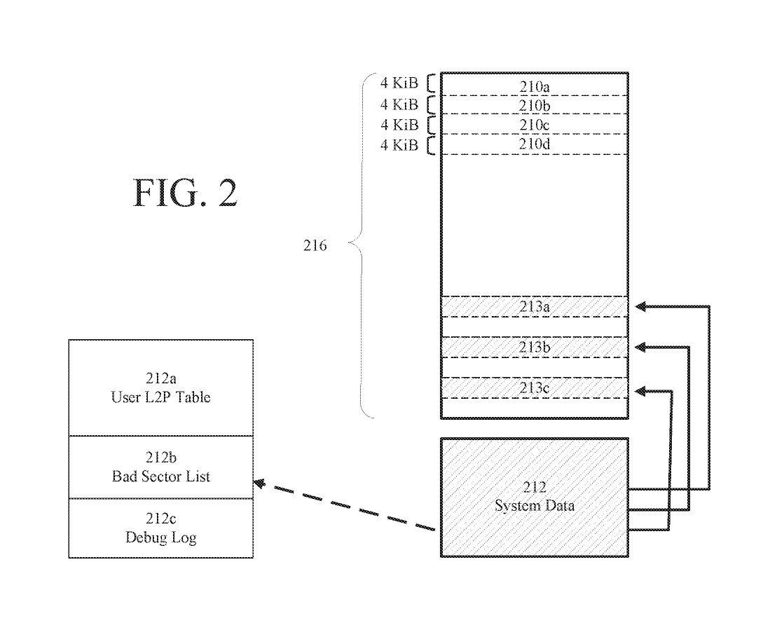

The NAND flash memory devices 104a-f include one or more blended data blocks storing a combination of user data and system data in the same format. In one embodiment, the NAND flash memory devices 104a-f also include a reserved area to which the memory controller 102 does not write data during regular operation of the SSD 100. The reserved area of the NAND flash memory devices 104a-f is used to store critical data structures when the SSD 100 experiences a power loss or other failure, as described below in connection with FIG. 2.

FIG. 2 shows the process of writing a system data 212 to a blended data block 216 storing user and system data on a NAND flash memory device, according to one embodiment of the invention. The memory controller, such as the memory controller 102 of SSD 100 shown and described in connection with FIG. 1, implements an algorithm for writing a user data received from the host device via the host interface. The memory controller writes the user data to the blended data block 216 as equal-sized segments of user data 210a-d. In one embodiment, each segment of user data 210a-d contains 4 kibibytes (4 KiB) or 4,096 bytes. While four 4 KiB segments of user data 210a-d are shown on the blended data block 216 in FIG. 2, the size of the segments of user data, the number of segments of user data, and the number of blended data blocks are not limited, and may be one or more segments of user data of any size stored on one or more blended data blocks within the scope of the present invention.

The memory controller generates system data 212. In one embodiment, the system data 212 includes a User L2P table 212a which translates the logical addresses of user data to the physical address locations of the user data in the NAND flash memory. The User L2P table 212a includes a first map and a second map. The first map translates the namespace identifier of each of the logical addresses of user data to the physical address location of the starting segment of the namespace. The second map translates the logical block of each of the logical addresses of user data to the physical address location of the logical block in the NAND flash memory. The memory controller uses the User L2P table 212a to perform data management processes on the user data, including garbage collection, error correction, and wear leveling.

In one embodiment, the system data 212 also includes a physical-to-logical (P2L) table (not shown). The P2L table is the reverse mapping of the User L2P table and translates the physical address locations of the user data in the NAND flash memory to the logical addresses of the user data. The P2L table includes a map that translates one or more physical address locations in the NAND flash memory to a logical address associated with a user or system data stored in the physical address location.

In one embodiment, the system data 212 includes a bad sector list 212b, a record of the physical address locations on the NAND flash memory that may be permanently damaged or otherwise unwriteable. In one embodiment, the system data 212 includes a debug log 212c, a record of actions performed by the SSD and errors that occurred during operation of the SSD for debugging purposes. In one embodiment, the system data includes firmware for the memory controller (not pictured).

To make the system data 212 look like user data 210a-d when it is stored on the blended data block 216, the memory controller divides the system data 212 into one or more equal-sized segments of system data 213a-c. Each segment of system data 213a-c contains 4 KiB, the same size as the segments of user data 210a-d. While three 4 KiB segments of system data 213a-c are shown on the blended data block 216 in FIG. 2, the size of the segments of system data, the number of segments of system data, and the number of blended data blocks are not limited, and may be one or more segments of system data of any size stored on one or more blended data blocks within the scope of the present invention.

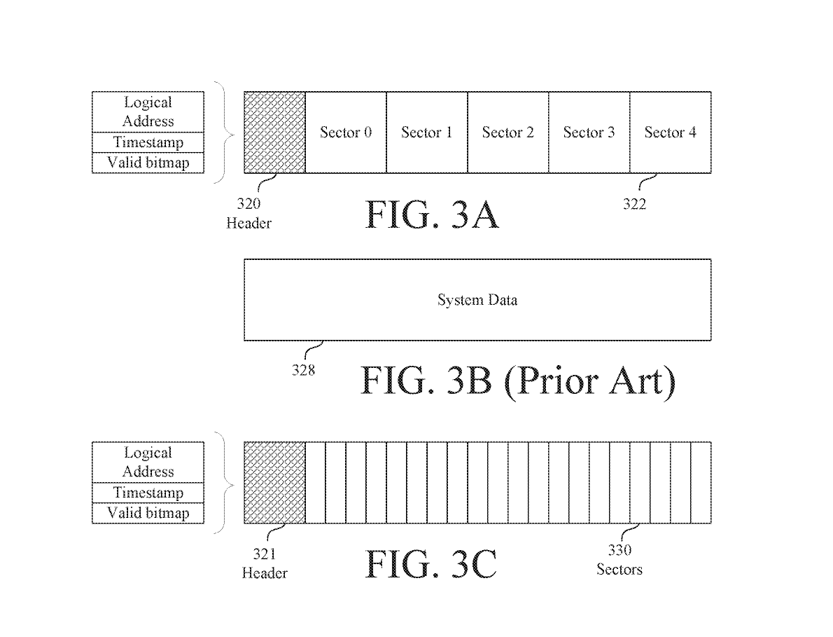

The memory controller also structures each segment of system data 213a-c to look like a segment of user data by appending a header (not shown) to the segment of system data before writing it to the blended data block 216. The appending of the header to the segment of system data 213a-c is shown and described in connection with FIG. 3C, below.

After the memory controller has altered the system data 212 to look like user data 210a-d by dividing the system data 212 into equal-sized segments and appending a header to each segment of system data 213a-c, the segments of system data 213a-c are written to the blended data block 216, where the segments of system data 213a-c are blended with the user data 210a-d. In this manner, the memory controller does not need to set aside a distinct area on the NAND flash memory for system data storage because the system data 213a-c is stored in the same format as user data 210a-d on a blended data block containing both user and system data.

In another embodiment, the memory controller generates a System L2P table (not shown), which is the complement to the User L2P table 212a. The memory controller generates a logical address for each segment of system data 213a-c stored in the NAND flash memory for internal use, as described below in connection with FIG. 3C. The System L2P table maps the logical addresses of system data 213a-c stored in the NAND flash memory to the physical address locations of the system data 213a-c. The System L2P table includes a first map and a second map. The first map translates the namespace identifier of each of the logical addresses of system data 213a-c to the physical address location of the starting segment of the namespace. In one embodiment, the first map of the System L2P table may be the same as the first map of the User L2P table (i.e. the namespace map is the same for both system and user data, but the namespace L2Ps are separate for system and user data). The second map translates the logical block of each of the logical addresses of system data 213a-c to the physical address location of the logical block in the NAND flash memory.

The System L2P table may be stored in a distinct area of the NAND flash memory. The System L2P table is very small in relation to the size of the system data. For example, in one embodiment, the system data 213a-c comprises approximately 800 mebibytes (800 MiB), while the System L2P table is approximately 800 KiB or 1/1024^{th} of the size of the system data 213a-c. The memory controller uses the System L2P table to perform data management processes on the system data 213a-c, including garbage collection, error correction, and wear leveling, and to read the User L2P table on the NAND flash memory for performing the same date management processes on the user data 210a-d.

In one embodiment, the System L2P table and the User L2P table can be a unified L2P table. As explained in greater detail below, once system data is written to the NAND flash memory, data management can be performed on the data on the NAND flash memory without distinction as to system or user data.

In another embodiment, when the SSD experiences a power loss or other failure, the memory controller is configured to rewrite the System L2P table to the reserved area of the NAND flash memory. The reserved area of the NAND flash memory ordinarily does not store data, as discussed above in connection with FIG. 1. In the prior art, the memory controller is typically configured to write the User L2P table to the reserved area. In this embodiment, upon a power loss or other failure event, the memory controller writes the System L2P table to the reserved area. Rewriting the System L2P table ensures that all user 210a-d and system data 213a-c is preserved and can be located by the memory controller. This is because the System L2P table identifies the physical address locations of the system data 213a-c on the NAND flash memory, including the User L2P table, which identifies the physical address locations of the user data 210a-d. The System L2P table is significantly smaller than the User L2P table, which allows the memory controller to write the System L2P table quickly to the reserved area when the SSD experiences a power loss or other failure, instead of writing the larger User L2P table. This reduces the length of time needed for back-up power sources (e.g. a battery or capacitor) to provide power to the SSD during a power loss or other failure event in order for the SSD to store critical data in the NAND flash memory before shutting down.

FIG. 3A shows a segment of user data stored on a NAND flash memory device, according to one embodiment of the invention. The segment of user data has a header 320 including information about the segment of user data. In one embodiment, the header 320 includes the logical address of the segment of user data. Each segment of user data on a NAND flash memory device has a physical address location and a logical address used by the host device to refer to the segment of user data. According to the NVMe (“non-volatile memory express”) interface standard for data storage in an SSD, data stored in the SSD is divided into multiple logical drives known as namespaces. The namespaces can be any size required by the host device. In one embodiment, each logical address includes two independent values: a namespace identifier and a logical block within that namespace.

In another embodiment, the header 320 includes a timestamp. In another embodiment, the header 320 includes a valid bitmap status. The information included in the header 320 is not limited to the information shown in FIG. 3A and may include any combination of information relating to the segment of user data within the scope of the present invention.

The segment of user data is further divided into five subdivisions known as sectors 322, Sector 0 through Sector 4. While five sectors 322 are shown within the segment of user data in FIG. 3A, the number of sectors and the size of each sector is not limited, and may be one or more sectors of any size within one segment of user data within the scope of the present invention.

FIG. 3B shows a system data 328 stored on a NAND flash memory device, according to the prior art. In the prior art, the memory controller writes the system data 328 to a distinct area of the NAND flash memory device that is separate from the area of the NAND flash memory device that stores user data. Because system data is not blended with user data in the prior art, the memory controller writes the system data 328 to the NAND flash memory device in a solid, uninterrupted block, without additional formatting.

FIG. 3C shows a segment of system data on a NAND flash memory device that has been configured to look like a segment of user data, according to one embodiment of the invention. The segment of system data has a header 321 including information about the segment of system data. In one embodiment, the header 321 includes the logical address of the segment of system data. The memory controller generates a logical address for each segment of system data. Logical addresses of system data are used internally by the SSD.

In one embodiment, each logical address includes a namespace identifier and a logical block within that namespace as described above in connection with FIG. 3A. In one embodiment, the memory controller creates one or more system namespaces used by the SDD for system data only and not for user data. The SSD uses the system namespaces internally to handle system data. The system namespaces can be of any size. In this embodiment, the memory controller generates a logical address for each segment of system data that is written to the NAND flash memory, comprising two independent values: 1) a namespace identifier for one of the one or more system namespaces, and 2) a logical block within the system namespace.

In another embodiment, the header 321 includes a timestamp. In another embodiment, the header 321 includes a valid bitmap status. The information contained in the header 321 is not limited to the information shown in FIG. 3C and may include any combination of information relating to the segment of system data within the scope of the present invention.

The segment of system data on the NAND flash memory device is further divided into five subdivisions known as sectors 330, sector A to sector E. While five sectors 330 are shown within the segment of system data in FIG. 3C, the number of sectors and the size of each sector is not limited, and may be one or more sectors of any size within one segment of system data within the scope of the present invention.

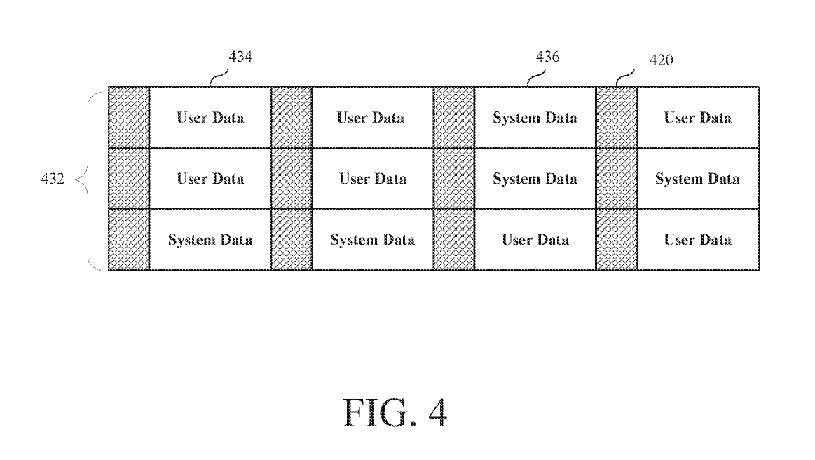

FIG. 4 shows a blended data block 432 of user data 434 and system data 436 on a NAND flash memory device, according to one embodiment of the invention. The blended data block 432 contains one or more segments of user data 434 interspersed with one or more segments of system data 436. Each segment of user or system data includes a header 420 as described in connection with FIGS. 3A and 3C, above.

Because the user data 434 and system data 436 are stored together in the blended data block 432 on the NAND flash memory device, and the system data 436 has been divided into segments and appended with a header 420 to look like user data 434, the memory controller can use the same algorithms to implement data management processes on the user data 434 and system data 436. The memory controller does not distinguish between user data 434 and system data 436 when running these algorithms.

In one embodiment, the memory controller implements wear leveling on one or more blended data blocks 432 of user data 434 and system data 436 stored in the NAND flash memory. When a blended data block 432 is rewritten, both the user data 434 and the system data 436 on the blended data block 432 are rewritten to a new physical location. Therefore, all of the one or more blended data blocks 432 are maintained at a similar number of P/E cycles at any given time. Because each blended data block 432 is at a similar number of P/E cycles, the memory controller does not need to use a different wear leveling algorithm for certain data blocks that are at a lower number of P/E cycles. The memory controller implements a single algorithm for wear leveling of all of the one or more blended data blocks 432 in the NAND flash memory.

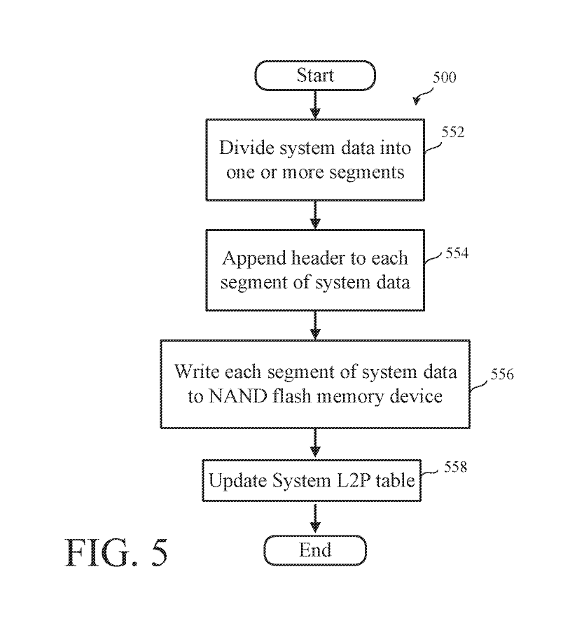

FIG. 5 shows steps 500 for writing system data to one or more NAND flash memory devices, according to one embodiment of the invention. At step 552, the system data is divided into one or more equal-sized segments, each segment of system data having the same size as the segments of user data stored on the one or more NAND flash memory devices. At step 554, a header is appended to each segment of system data to make the segment of system data look like a segment of user data. The header may include a logical address, a timestamp, a valid bitmap status, or any combination thereof, as discussed above in connection with FIG. 3C. At step 556, each segment of system data is written to the one or more NAND flash memory devices. At step 558, a System L2P table is updated to reflect the logical address and the physical address location of each segment of system data that was written to the one or more NAND flash memory devices.

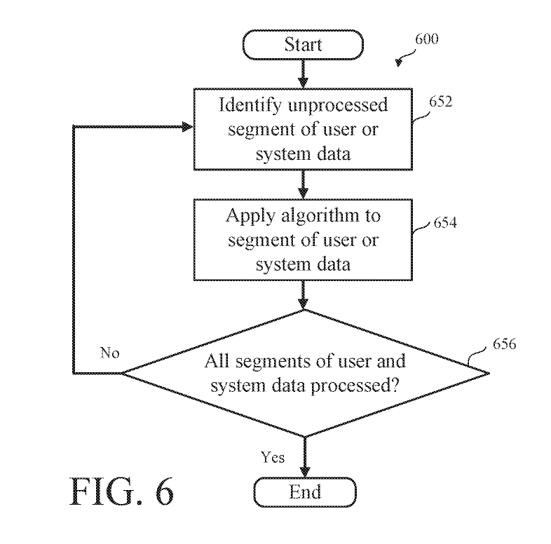

FIG. 6 shows steps 600 for processing a blended data block of user and system data on one or more NAND flash memory devices, according to one embodiment of the invention. At step 652, a segment of user or system data on the one or more NAND flash memory devices that has not been processed is chosen. At step 654, an algorithm is applied to the segment of user or system data to process it. The algorithm may include any algorithm for managing the data, including garbage collection, error correction, wear leveling, RAID recovery, background scanning, and any combination thereof. The same algorithm is applied whether the data is user data or system data. At step 656, if not every segment of user or system data on the one or more NAND flash memory devices has been processed, then step 652 is repeated until every segment of user or system data is processed and the processing concludes.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Similarly, principles according to the present invention could be applied to other examples, which, even if not specifically described here in detail, would nevertheless be within the scope of the present invention.

What is claimed is:

1. A solid state drive (SSD) comprising:
a memory controller;
one or more NAND flash memory devices communicatively coupled to the memory controller; and
a host interface communicatively coupled to the memory controller,
wherein the memory controller is configured to write both a user data received via the host interface and a system data generated by the memory controller to one or more blocks of the NAND flash memory devices such that the one or more blocks contain both user data and system data.

2. The SSD of claim 1, wherein the system data includes at least one of a bad sector list, a debug log, and firmware.

3. The SSD of claim 1, wherein the memory controller is further configured to divide the system data into one or more segments having a uniform size, and append a header to each segment of system data before writing the system data to the one or more blocks of the NAND flash memory devices.

4. The SSD of claim 3, wherein the header includes at least one of a logical address associated with a segment of user or system data, a timestamp, and a valid bitmap status.

5. The SSD of claim 1, wherein the NAND flash memory devices are configured to store user data and system data in one or more segments, each segment of user data and each segment of system data having a physical address location on the NAND flash memory device and a logical address comprising a namespace identifier indicating a namespace and a logical block within the namespace.

6. The SSD of claim 5, wherein the memory controller is further configured to assign a namespace identifier to each segment of system data.

7. The SSD of claim 5, wherein the system data comprises a user logical-to-physical (User L2P) table translating logical addresses of one or more segments of user data physical address locations.

8. The SSD of claim 7, wherein the User L2P table comprises a first map translating the namespace identifier of each of the one or more logical address to a starting segment of user data on the one or more NAND flash memory devices, and a second map translating the logical block of each of the one or more logical address to a segment of user data on the one or more NAND flash memory devices.

9. The SSD of claim 5, wherein the memory controller is further configured to write a system logical-to-physical (System L2P) table translating logical addresses of one or more segments of system data to one or more physical address locations of the segments of system data on the NAND flash memory devices.

10. The SSD of claim 9, wherein the System L2P table comprises a first map translating the namespace identifier of each of the one or more logical addresses to a starting segment of system data on the one or more NAND flash memory devices, and a second map translating the logical block of each of the one or more logical addresses to a segment of system data on the one or more NAND flash memory devices.

11. A method of writing user data and system data to one or more NAND flash memory devices communicatively coupled to a memory controller within a solid state drive (SSD), the method comprising:
receiving the user data via a host interface communicatively coupled to the memory controller;
generating the system data with the memory controller; and
writing both the user data and the system data to one or more blocks of the NAND flash memory devices such that the one or more blocks contain both user data and system data.

12. The method of claim 11, wherein the system data includes at least one of a bad sector list, a debug log, and firmware.

13. The method of claim 11, further comprising:
dividing the system data into one or more segments having a uniform size; and
appending a header to each segment of system data before writing the system data to the one or more blocks of the NAND flash memory devices.

14. The method of claim 13, wherein the header includes at least one of a logical address associated with a segment of user or system data, a timestamp, and a valid bitmap status.

15. The method of claim 11, further comprising:
writing the user data and system data in one or more segments, each segment of user data and each segment of system data having a physical address location on the NAND flash memory devices and a logical address comprising a namespace identifier indicating a namespace and a logical block within the namespace.

16. The method of claim 15, further comprising:
assigning a namespace identifier to each segment of system data before writing both the user data and the system data to one or more blocks of the NAND flash memory devices such that the one or more blocks contain both user data and system data.

17. The method of claim 15, wherein the system data comprises a user logical-to-physical (User L2P) table translating logical addresses of one or more segments of user data to physical address locations.

18. The method of claim 11, wherein the User L2P table comprises a first map translating the namespace identifier of each of the one or more logical addresses to a starting segment of user data on the one or more NAND flash memory devices, and a second map translating the logical block of each of the one or more logical addresses to a segment of user data on the one or more NAND flash memory devices.

19. The method of claim 15, further comprising:
writing to the NAND flash memory devices a system logical-to-physical (System L2P) table translating logical addresses of one or more segments of system data to one or more physical address locations of the segments of system data on the NAND flash memory devices.

20. The method of claim 19, wherein the System L2P table comprises a first map translating the namespace identifier of each of the one or more logical addresses to a starting segment of system data on the one or more NAND flash memory devices, and a second map translating the logical block of each of the one or more logical addresses to a segment of system data on the one or more NAND flash memory devices.
